(19) United States
(12) Patent Application Publication
(10) Pub. No.: US 2024/0250060 A1
(43) Pub. Date: Jul. 25, 2024

(54) CAPILLARY FOR STITCH BOND

(71) Applicant: Texas Instruments Incorporated, Dallas, TX (US)

(72) Inventors: Ye Zhuang, Chengdu (CN); Huo Yun Duan, Chengdu (CN); Zi Qi Wang, Chengdu (CN); Xiao Lin Kang, Chengdu (CN); Xiaoling Kang, Chengdu (CN); Tingting Yu, Chengdu (CN)

(21) Appl. No.: 18/158,982

(22) Filed: Jan. 24, 2023

(51) Int. Cl. H01L 23/00

(52) U.S. Cl. CPC H01L 24/78; H01L 24/32; H01L 24/48; H01L 24/73; H01L 24/85; H01L 2224/32245; H01L 2224/48245; H01L 2224/48465; H01L 2224/73265; H01L 2224/78304; H01L 2224/85181; H01L 2224/85947; H01L 2924/13091

(57) ABSTRACT

An example semiconductor package comprises a semiconductor die having a top surface, a bond pad formed on the top surface, a bond wire having a first end and a second end, wherein the first end is attached to the bond pad. The semiconductor package having a contact pad, wherein the second end of the wire bond is attached to the contact pad by a stitch bond, the stitch bond having a plateau region formed between a cut end and a ramped portion, wherein a bottom surface of the plateau region forms an attachment to the contact pad.

### BACKGROUND

Semiconductor devices including active and/or passive components may be manufactured into round wafers sliced from elongated cylinder-shaped single crystals of semiconductor elements or compounds. The diameter of these solid-state wafers may reach up to 12 inches or more. Individual semiconductor dies are typically singulated from a round wafer by sawing streets in X-and Y-directions through the wafer in order to create rectangularly shaped discrete pieces from the wafers.

Each semiconductor die includes at least one active or passive component and bond pads serving to facilitate electric connections to the components of the semiconductor die. A bond pad may be a build-up layer of metal, such as aluminum or thick copper with nickel palladium plating, over a metallization layer of a semiconductor die. Semiconductor dies include many large families of functional circuits; examples include active devices such as diodes and transistors like field-effect transistors, passive devices such as resistors and capacitors, and integrated circuits, which can include far more than a million active and passive components.

After singulation, one or more semiconductor dies are attached to a discrete supporting substrate such as a metal leadframe or a rigid multi-level substrate laminated from a plurality of metallic and insulating layers. The conductive traces of the leadframes and substrates are connected to the bond pads, typically using wire bonds or metal bumps such as solder bumps.

Leadframes may include a pad and one or more leads. The pad serves as a substrate providing a stable support for firmly positioning a semiconductor die within the semiconductor package during manufacturing, whereas the leads provide electrical connections from outside the package to the active surface of the semiconductor die. Gaps between the inner end of the leads and contact pads on the active surface of the semiconductor die are bridged by connectors, typically with wire bonds comprising thin metal wires, such as gold or copper wires, that are individually bonded to both the bond pads and the leads. The bond to the lead is often referred to as a stitch bond and formed by applying force that presses the wire against the lead forming an attachment between the wire and lead and cutting the bond wire.

The assembled semiconductor dies, leadframes, and/or substrates may be encapsulated to form discrete robust packages, which frequently employ hardened polymeric compounds and are formed by techniques such as transfer molding. The assembly and packaging processes are performed either on an individual basis or as part of batch processes including a strip or array of semiconductor dies on a corresponding strip or array of leadframes. In batch processes, mold compound may be applied to all packages of leadframe strip through a single loading of a mold press.

### SUMMARY

In an arrangement, a semiconductor package comprises a semiconductor die having a top surface, a bond pad formed on the top surface, a bond wire having a first end and a second end, wherein the first end is attached to the bond pad. The semiconductor package having a contact pad, wherein the second end of the wire bond is attached to the contact pad by a stitch bond, the stitch bond having a plateau region formed between a cut end and a ramped portion, wherein a bottom surface of the plateau region forms an attachment to the contact pad. The plateau region has a uniform thickness.

The plateau region has a top surface that is generally parallel to the bottom surface. The plateau region has a thickness that is determined by a height of a boss portion of a capillary tool. The plateau region has a thickness that is between 20 and 30 percent of a diameter of the bond wire. The semiconductor package of claim 1, wherein the plateau region has a width that is between 50 and 100 percent wider than a width of the bond wire.

The ramped portion provides a transition between a plateau region thickness and a thickness of the bond wire.

The first end of the bond wire may be attached to the bond pad by a ball bond.

In another arrangement, a method for forming a stitch bond for a semiconductor package comprises forming a first bond between a first end of a conductive wire and a semiconductor die using capillary tool, positioning the capillary tool over a second bond site, and moving the capillary tool to contact the second bond site so that the conductive wire is cut to create a second end, the second end forming the stitch bond at the second site, the stitch bond having a plateau region formed between a cut end and a ramped portion of the conductive wire, wherein a bottom surface of the plateau region forms an attachment to the second bond site.

The first bond may be a ball bond formed on a bond pad on the semiconductor die. The second bond site may be a lead on a leadframe.

Contact between the capillary and the second bond site creates a plateau region with a uniform thickness. The plateau region having a top surface that is generally parallel to the bottom surface. The plateau region having a thickness that is determined by a height of a boss portion of a capillary tool. The plateau region having a thickness that is between 20 and 30 percent of a diameter of the conductive wire. The plateau region has a width that is between 50 and 100 percent wider than a width of the conductive wire.

The ramped portion may provide a transition between a plateau region thickness and a thickness of the conductive wire.

In a further arrangement, a wire bond in a semiconductor package comprises a bond pad formed on the top surface of a semiconductor die, a conductive wire having a first end and a second end, wherein the first end is attached to the bond pad, and a contact pad, wherein the second end of the conductive wire is attached to the contact pad by a stitch bond, the stitch bond having a plateau region formed between a cut end and a ramped portion, wherein a bottom surface of the plateau region forms an attachment to the contact pad. The plateau region has a uniform thickness, the plateau region having a top surface that is generally parallel to the bottom surface, the plateau region thickness determined by a height of a boss portion of a capillary tool, wherein the ramped portion provides a transition between a plateau region thickness and a thickness of the conductive wire. The plateau region has a thickness that is between 20 and 30 percent of a diameter of the conductive wire, the plateau region has a width that is between 50 and 100 percent wider than a width of the conductive wire, and wherein the first end of the bond wire is attached to the bond pad by a ball bond.

### BRIEF DESCRIPTION OF THE DRAWINGS

Having thus described the invention in general terms, reference will now be made to the accompanying drawings, wherein:

FIG. 1 is a perspective view of a portion of a semiconductor package including wire bonds extending from the ball bonds on a semiconductor die to stitch bonds on a leadframe.

FIG. 2 is a detailed view of a wire bond showing a ball bond attached to a bond pad on a semiconductor die and a stitch bond connected to a lead.

FIGS. 3A-D schematically illustrate a wire bonding process using a stitch bond as disclosed herein.

FIGS. 4A and $b are side views showing a capillary creating a stitch bond the top surface of a lead or contact.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “capillary” is used herein. A capillary is a tool used for wirebonding or to electrically connect contacts within a semiconductor package. The capillary may be used to form ball bonds at one end of a wire. The ball bond is typically attached to a bond pad on a semiconductor device. The capillary may also be used to form stitch bonds at another end of the wire. The stitch bond may be attached to a contact such as a lead portion of a leadframe. The capillary cuts the wire and completes a wire bond when the stitch bond is formed.

The term “ball bond” is used herein. A ball bond is an attachment between a bond wire and a pad on a semiconductor die. A ball of metal is formed by heating and melting one end of a bond wire. The ball bond is formed by pressing the metal ball against the semiconductor die pad. The bond wire remains connected to the ball bond and is electrically coupled to the semiconductor die pad.

The term “stitch bond” is used herein. A stitch bond is an attachment between a bond wire and a bond pad or lead. The stitch bond is formed by pressing or squashing the bond wire against the bond pad or lead, which results in a flattened segment of the bond wire that is metallurgically bonded to the bond pad or lead to create an electrical connection. The stitch bond is formed using a capillary and is usually the second connection on a wire bond following creating of a ball bond connection first.

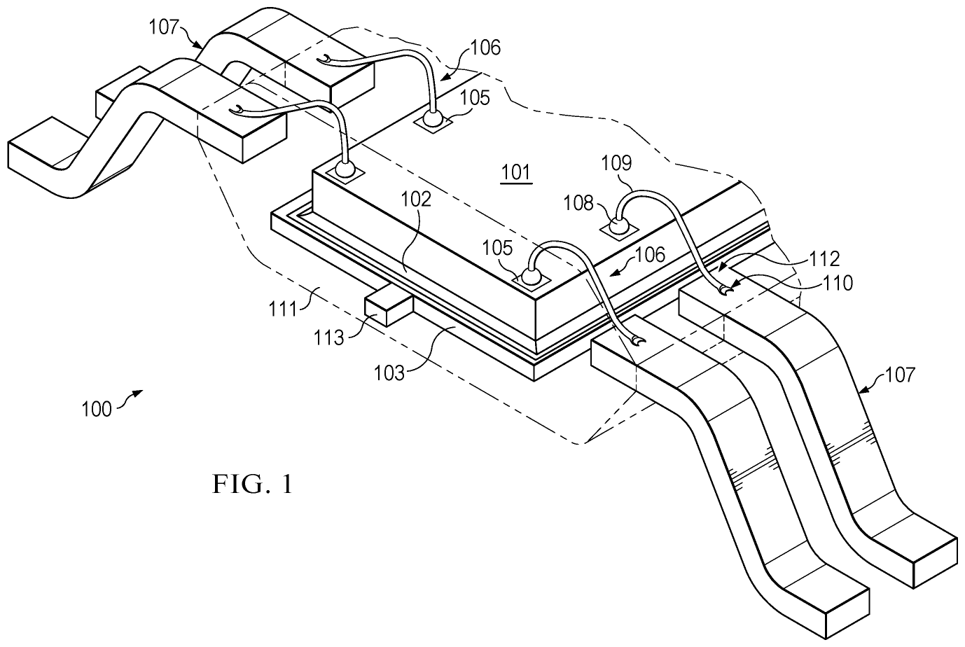

FIG. 1 is a perspective view of a portion of semiconductor package 100 including a semiconductor die 101 bonded with a die attach adhesive 102 onto a metallic die attach pad 103 of a metallic leadframe 104. Bond pads 105 of semiconductor die 101 are electrically connected by wire bonds 106 to respective leads 107 of leadframe 104. Bond pads 105 on semiconductor die 101 may be aluminum pads over a dielectric layer of semiconductor die 101. In accordance with the techniques of this disclosure, each of wire bonds 106 include a ball bond 108 on one end of a wire 109 to connect to a respective bond pad 105 and a stitch bond 110 on the other end of the wire 109 to connect to a respective lead 107. Wires 109 of wire bonds 106 may be made of electrically conductive copper or copper alloys. In some examples, wires 109 may have diameters between about 10 μm to 25 μm.

Semiconductor package 100 further includes a mold compound 111 covering die attach pad 103, semiconductor die 101, bond pad 105, ball bond 108, wire 109, stitch bond 110, and an end portion 112 of each lead 107. Exposed portions of leads 107 of leadframe 104 enable attachment to external devices and circuits, such as a printed circuit board (not shown). Leadframe 104 may further includes tie bars 113 that extend between die attach pad 103 to an external surface of semiconductor package 100. Tie bars 113 function to support die attach pad 103 within a leadframe strip prior to molding of mold compound 111 and singulation of semiconductor package 100 from an array of semiconductor packages manufactured on a common leadframe strip.

Semiconductor die 101 may include any combination of semiconductor elements such as transistors and integrated circuits. In various examples of this disclosure, semiconductor die 101 may be implemented using any semiconductor material employed in industry, such as a silicon, gallium arsenide, gallium nitride, silicon germanium, or other semiconductor material. In addition, the techniques of this disclosure may be applied to semiconductor packages with any combination of active and passive components on a leadframe in addition to semiconductor die 101.

Leadframe 104 includes die attach pad 103 and leads 107 spaced from die attach pad 103 by a gap. Die attach pad 103 is a substrate providing a stable support for firmly positioning semiconductor die 101 within semiconductor package 100. Leads 107 are shaped as cantilevered leads; in other examples, the leads may have other configurations, including but not limited to, the shape of flat leads as used in Quad Flat No-Lead (QFN) devices or in Small Outline No-Lead (SON) devices.

Leadframes, such as leadframe 104, are formed on a single sheet of metal by stamping or etching. Multiple interconnected leadframes may be formed from a single sheet of substrate, the interconnected leadframes referred to as a leadframe strip. Leadframes on the sheet can be arranged in rows and columns. Tie bars, such as tie bar 113, interconnect leads and other elements of a leadframe to one another as well as to elements of adjacent leadframes in a leadframe strip. A siderail may surround the array of leadframes to provide rigidity and support leadframe elements on the perimeter of the leadframe strip. The siderail may also include alignment features to aid in manufacturing.

Usually die mounting, die to lead attachment, such as wire bonding, and molding to cover at least part of the leadframe and dies take place while the leadframes are still integrally connected as a leadframe strip. After such processes are completed, the leadframes, and sometimes mold compound of a package, are severed (“singulated” or “diced”) with a cutting tool, such as a saw or laser. These singulation cuts separate the leadframe strip into separate semiconductor packages, each semiconductor package including a singulated leadframe, at least one die, electrical connections between the die and leadframe (such as gold or copper wire bonds) and the mold compound which covers at least part of these structures.

Tie bars and siderails may be removed during singulation of the packages formed with a single leadframe strip. The term leadframe of represents the portions of the leadframe strip remaining within a package after singulation. With respect to semiconductor package 100, leadframe 104 includes die attach pad 103, tie bar 113, and leads 107, although some of these elements are not interconnected following singulation of semiconductor package 100 into a discrete package.

Semiconductor die 101 is bonded on die attach pad 103 with die attach adhesive 102. Adhesive 102 includes a plurality of components including a resin. The resin may include epoxy resins, polyurethane resins, and/or silicone resins. The resin may be filled or unfilled. The die attach adhesive 102 may further include one or more of the following: hardener, curing agent, fused silica, inorganic fillers, catalyst, flame retardants, stress modifiers, adhesion promoters, and other suitable components. Fillers, if any, may be selected to modify properties and characteristics of the resin base materials. Inert inorganic fillers may be selected to lower the coefficient of thermal expansion, for example, to match semiconductor die 101, increase thermal conductivity, and/or increase elastic modulus of adhesive 102 compared to the resin base. Particulate fillers may be selected to reduce strength characteristics such as tensile strength and flexural strength compared to the resin base materials.

Semiconductor die 101, die attach pad 103, bond pads 105, and wire bonds 106 are covered by mold compound 111. End portions 112 of leads 107, which carry stitch bonds 110, are also covered by mold compound 111, while leads 107 extend to an exterior surface of the mold compound to facilitate electrical connections between package 100 and external components. Mold compound 111 provides a protective outer layer for semiconductor die 101 and wire bonds 106 formed in a molding process. In some examples, mold compound 111 includes an epoxy such as an epoxy-based thermoset polymer.

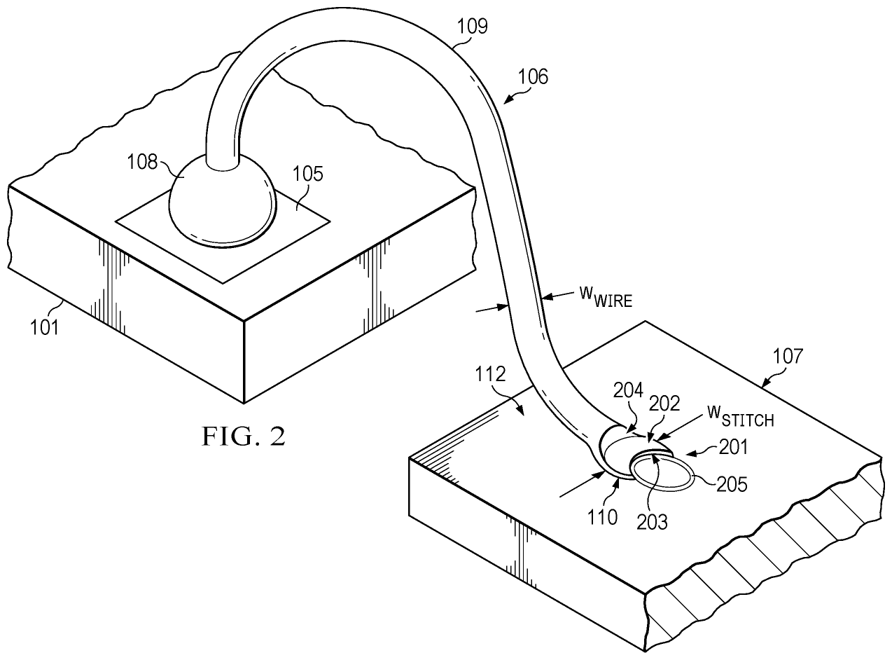

FIG. 2 is a detailed view of a wire bond 106 showing ball bond 108 attached to bond pad 105 on semiconductor die 101 and stitch bond 110 connected to lead 107. As discussed in more detail below, ball bond 108 and stitch bond 110 are formed by a capillary tool when wire bond 106 is attached to semiconductor die 101 and lead 107. The capillary used in one arrangement creates a stitch bond 110 having the shape shown in FIG. 2. Stitch bond 110 is formed when the capillary presses an end portion 201 of wire 109 down against the end portion 112 of lead 107. This downward pressure crushes wire 109 against end portion 112 and breaks the wire 109.

The crushed portion of wire 109 forms a generally flat plateau region 202 that attaches to the lead 107 and forms a conductive connection between lead 107 and wire 109. The capillary cuts or pinches off the wire at cut edge 203. Wire 109 has a width W_{WIRE}, which may be between 10 μm to 25 μm in one embodiment. The plateau region 202 of stitch bond 110 spreads out laterally and has a width W_{STITCH} that may be approximately 50-100% wider than the width W_{WIRE} of wire 109. The creation of stitch bond 110 results in a ramped portion 204 that forms a transition between the body of wire 109 and the plateau region 202. The force between the capillary tool and lead 107 when wire 109 is cut may create a witness mark 205 on the surface of lead 107.

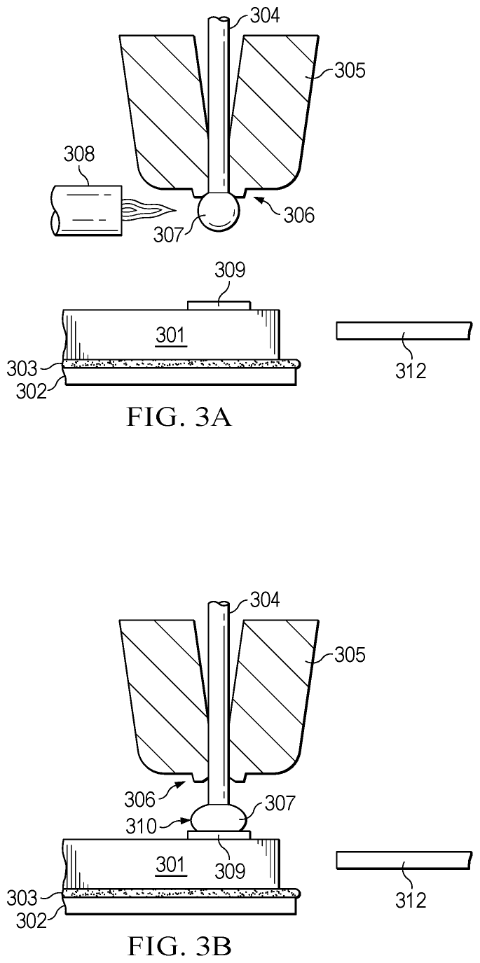

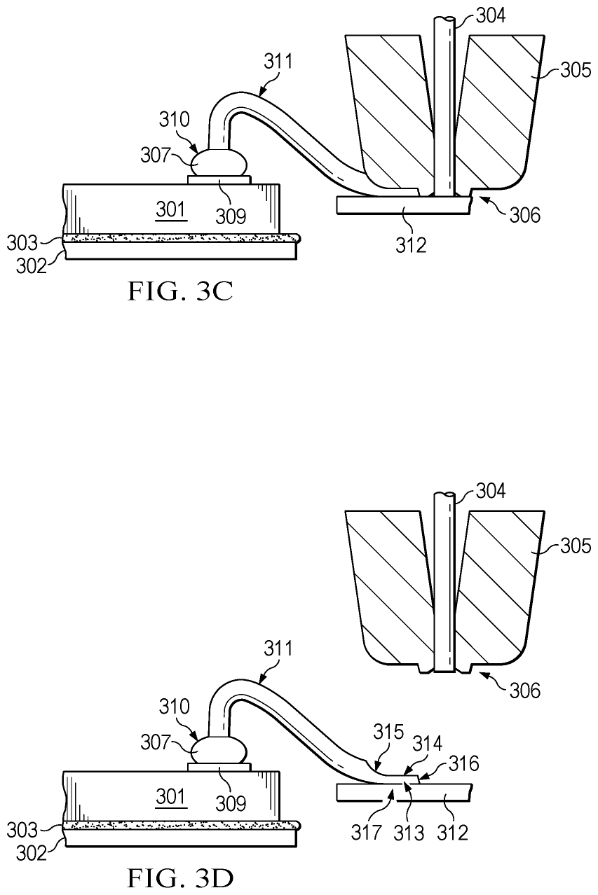

FIGS. 3A-D schematically illustrate a wire bonding process using a stitch bond as disclosed herein. In FIG. 3A, the process begins by positioning a semiconductor chip 301 attached to a substrate 302, such as a die attach pad of a leadframe, using a die attach material 303. A wire 304 is strung through a capillary 305 and extends a short distance outside the tip 306 of the capillary 305. As an example, wire 304 may be a gold wire or a lead (Pb) coated copper (PCC) wire. A free air ball 307 is created at the end of wire 304 using either a flame or a spark technique 308. The ball 307 may have a typical diameter of about 1.2 to 4.0 wire diameters. Ball 307 is formed outside of the capillary 305.

In FIG. 3B, the capillary 305 is moved towards a bonding pad 309 on semiconductor die 301. Ball 309 is pressed by the capillary 305 against the metallization of the bonding pad 309. In this process, the ball 309 is deformed, but for the sake of convenience it is still referred to as the “ball” of the bond 310. After formation of the ball bond 310, which may involve ultrasonic energy in addition to the compression force from capillary 305, the capillary 305 is lifted straight upward in order to avoid wire bending at least for a length of a heat-affected wire zone.

In FIG. 3C, after completing the ball bond 310, capillary 305 moves in a pre-determined and computer-controlled manner through the air to create a wire arch 311 shape before the capillary 305 attaches wire 304 to lead 312. Wire 304 is attached to lead 312 by a stitch bond 313. The shape of the stitch bond 313 is determined by the shape of tip 306 on capillary 305.

In FIG. 3D, after cutting wire 304 by pinching wire 304 between end 306 and lead 312, the capillary 305 moves upward away from lead 312 and stitch bond 313. Capillary end 306 is configured to form a stitch bond 313 as shown in cross section in FIG. 3D. Stich bond 313 has a plateau portion 314 that extends between a ramped portion 315 and a cut end 316. The plateau region 314 creates a bond area 317 on the underside of wire 304 that securely attaches wire 304 to lead 312. In prior stitch bond techniques, the bond wire would terminate in a ramped section 315 that sloped down to the surface of lead 312, which provided less bonding surface than shown in FIG. 3D using the technique illustrated herein. This ramped terminal end on prior stitch bonds allowed the bond to break or detach from lead 312 since there was less bonding area 317.

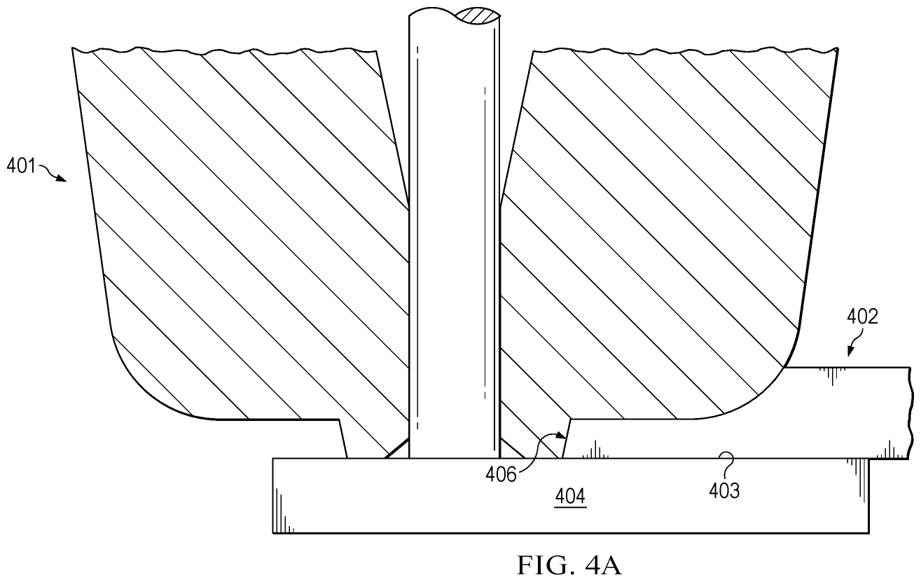

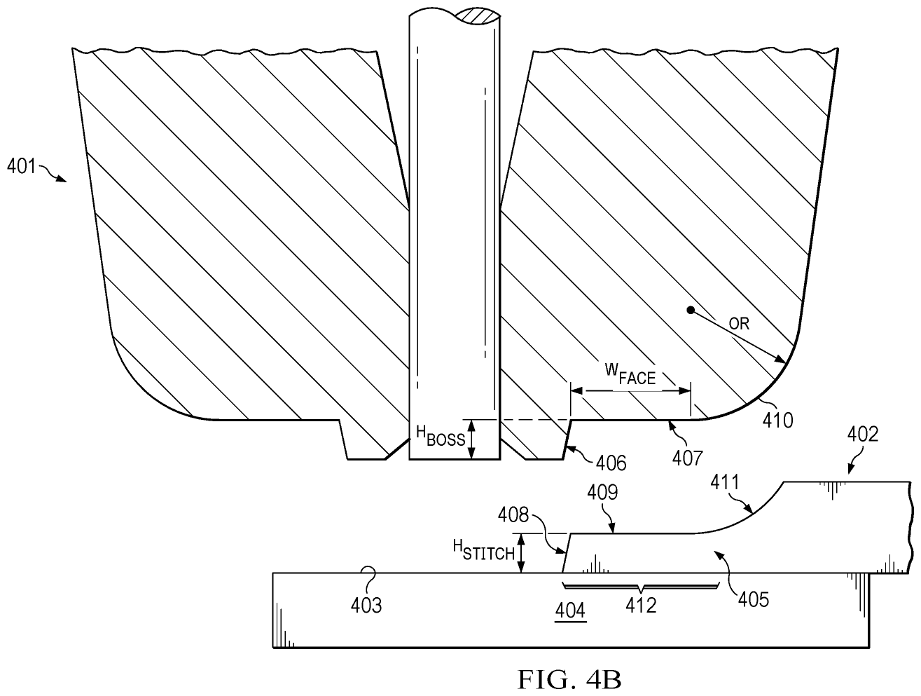

FIG. 4A is a side view showing a capillary 401 pressing a wire 402 against a surface 403, such as the top surface of a lead or contact 404. Wire 402 is conductively bonded to surface 403 by capillary 401 using a stitch bond. FIG. 4B shows the stitch bond 405 that is created after capillary 401 is moved up and away from wire 402. In one arrangement, capillary 401 is configured to accept a wire 402 having a 25.4 μm diameter, such as a gold or PCC wire. Capillary 401 is generally a hollow tube shape. The lower end of capillary 401 has boss portion 406 that extends beyond a face portion 407.

In one arrangement, boss portion 406 has a height H_{BOSS} of 6±1 μm, and face portion 407 has a width W_{FACE} of 20 μm. The boss height H_{BOSS} is selected to set the stitch thickness H_{STITCH} and thereby control the bondability of stitch bond 405. Boss 406 also cuts wire 402 during the creation of the stitch bond 405, which terminates in a cut end 408. The face portion 407 is a horizontal section that is generally perpendicular to surface 403 so that the face angle (i.e., the angle between face portion 407 and surface 403 is approximately zero degrees. Face portion 407 allows the force generated by capillary 401 to be distributed evenly across wire 402 to create the flat shape of stitch bond 405. A plateau portion 409 on stitch bond 405 is created by face portion 407 of capillary 401. An outside edge 410 of capillary 401, having an outer radius OR, creates a ramped or sloped portion 411 of stitch bond 405, which transitions between the plateau portion 409 and the body of wire 402. The design of capillary 401 increases the effective bonding area 412 of stitch bond 405 and avoids the thinner stitch shape that was generated by previous capillary designs.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a semiconductor die having a top surface;
a bond pad formed on the top surface;
a bond wire having a first end and a second end, wherein the first end is attached to the bond pad; and
a contact pad, wherein the second end of the bond wire is attached to the contact pad by a stitch bond, the stitch bond having a plateau region formed between a cut end and a ramped portion, wherein a bottom surface of the plateau region forms an attachment to the contact pad.

2. The semiconductor package of claim 1, wherein the plateau region has a uniform thickness.

3. The semiconductor package of claim 1, wherein the plateau region has a top surface that is generally parallel to the bottom surface.

4. The semiconductor package of claim 1, wherein the plateau region has a thickness that is determined by a height of a boss portion of a capillary tool.

5. The semiconductor package of claim 1, wherein the plateau region has a thickness that is between 20 and 30 percent of a diameter of the bond wire.

6. The semiconductor package of claim 1, wherein the ramped portion provides a transition between a plateau region thickness and a thickness of the bond wire.

7. The semiconductor package of claim 1, wherein the plateau region has a width that is between 50 and 100 percent wider than a width of the bond wire.

8. The semiconductor package of claim 1, wherein the first end of the bond wire is attached to the bond pad by a ball bond.

9. A method for forming a stitch bond for a semiconductor package, comprising:
forming a first bond between a first end of a conductive wire and a semiconductor die using capillary tool;
positioning the capillary tool over a second bond site; and
moving the capillary tool to contact the second bond site so that the conductive wire is cut to create a second end, the second end forming the stitch bond at the second site, the stitch bond having a plateau region formed between a cut end and a ramped portion of the conductive wire, wherein a bottom surface of the plateau region forms an attachment to the second bond site.

10. The method of claim 9, wherein the first bond is a ball bond formed on a bond pad on the semiconductor die.

11. The method of claim 9, wherein the second bond site is a lead on a leadframe.

12. The method of claim 9, wherein contact between the capillary and the second bond site creates a plateau region with a uniform thickness.

13. The method of claim 9, wherein the plateau region has a top surface that is generally parallel to the bottom surface.

14. The method of claim 9, wherein the plateau region has a thickness that is determined by a height of a boss portion of a capillary tool.

15. The method of claim 9, wherein the plateau region has a thickness that is between 20 and 30 percent of a diameter of the conductive wire.

16. The method of claim 9, wherein the ramped portion provides a transition between a plateau region thickness and a thickness of the conductive wire.

17. The method of claim 9, wherein the plateau region has a width that is between 50 and 100 percent wider than a width of the conductive wire.

18. A wire bond in a semiconductor package, comprising:
a bond pad formed on the top surface of a semiconductor die;
a conductive wire having a first end and a second end, wherein the first end is attached to the bond pad; and
a contact pad, wherein the second end of the conductive wire is attached to the contact pad by a stitch bond, the stitch bond having a plateau region formed between a cut end and a ramped portion, wherein a bottom surface of the plateau region forms an attachment to the contact pad.

19. The wire bond of claim 18, wherein the plateau region has a uniform thickness, the plateau region having a top surface that is generally parallel to the bottom surface, the plateau region thickness determined by a height of a boss portion of a capillary tool; and
wherein the ramped portion provides a transition between a plateau region thickness and a thickness of the conductive wire.

20. The wire bond of claim 18, wherein the plateau region has a thickness that is between 20 and 30 percent of a diameter of the conductive wire, the plateau region has a width that is between 50 and 100 percent wider than a width of the conductive wire, and wherein the first end of the bond wire is attached to the bond pad by a ball bond.
